(19) United States
(12) Patent Application Publication
(10) Pub. No.: US 2020/0386479 A1
(43) Pub. Date: Dec. 10, 2020

(54) COOLING SYSTEM

(71) Applicants: Inventec (Pudong) Technology Corporation, Shanghai (CN); INVENTEC CORPORATION, TAIPEI CITY (TW)

(72) Inventors: Kai-Yang TUNG, TAIPEI CITY (TW); Hung-Ju CHEN, TAIPEI CITY (TW)

(21) Appl. No.: 16/575,371

(22) Filed: Sep. 18, 2019

(30) Foreign Application Priority Data
Jun. 5, 2019 (CN) 201910485499.2

(51) Int. Cl. F28D 1/02; H05K 7/20

(52) U.S. Cl. CPC F28D 1/0213; H05K 7/20336; H05K 7/20318; H05K 7/203

(57) ABSTRACT

A cooling system includes a housing, a dielectric liquid and a dielectric vapor. The housing has an accommodating space configured to accommodate a heat generating component. The dielectric liquid partially fills the accommodating space and is configured to contact the heat generating component. The dielectric vapor partially fills the accommodating space and is configured to contact the housing.

### RELATED APPLICATIONS

This application claims priority to China Application Serial Number 201910485499.2, filed Jun. 5, 2019, the disclosure of which is incorporated herein by reference in its entirety.

### BACKGROUND

### Technical Field

The present disclosure relates to a cooling system for electronic devices.

### Description of Related Art

In some demanding operating environments (e.g., embedded systems for vehicles, edge computing, etc.), electronic systems are required to be fanless because of the environmental constraints that inhibits the use of cooling fans. Conventional fanless systems typically make use of metal block(s) installed inside the chassis to contact the heat source, thereby transferring the heat generated by the heat source to the chassis and further dissipating the heat to the surrounding environment. A drawback with said approach is that in order to bring the heat source into thermal contact with the chassis, the interior of the chassis must be designed based on the arrangement of the heat source, and a component lower in height needs to be paired up with a structure like a boss to be able to contact the chassis. Consequently, conventional fanless systems are more costly and more time consuming to manufacture, and have low shareability.

In addition, heat conduction alone cannot effectively transfer heat to the chassis to eliminate local high temperature, further imposing constraints on the arrangement/configuration of the system.

### SUMMARY

In view of the foregoing, one of the objects of the present disclosure is to provide a cooling system with higher design flexibility and improved cooling efficiency for electronic devices.

To achieve the objective stated above, in accordance with an embodiment of the present disclosure, a cooling system includes a housing, a dielectric liquid and a dielectric vapor. The housing has an accommodating space configured to accommodate a heat generating component. The dielectric liquid partially fills the accommodating space and is configured to contact the heat generating component. The dielectric vapor partially fills the accommodating space and is configured to contact the housing.

In one or more embodiments of the present disclosure, the heat generating component is completely immersed in the dielectric liquid.

In one or more embodiments of the present disclosure, a viscosity of the dielectric liquid is lower than a viscosity of a mineral oil.

In one or more embodiments of the present disclosure, a surface tension of the dielectric liquid is lower than a surface tension of a mineral oil.

In one or more embodiments of the present disclosure, the cooling system further includes a heatsink disposed on an outer surface of the housing.

In one or more embodiments of the present disclosure, the heatsink is located on a side of the dielectric vapor away from the dielectric liquid.

In one or more embodiments of the present disclosure, the heatsink includes a plurality of fins.

In one or more embodiments of the present disclosure, the cooling system further includes a conduit in communication with the accommodating space and protruding out of the housing. The dielectric vapor is configured to at least partly flow into the conduit.

In one or more embodiments of the present disclosure, the cooling system further includes a heatsink disposed on an outer surface of the housing. The heatsink has at least one through hole. The conduit passes through the through hole and contacts the heatsink.

In one or more embodiments of the present disclosure, the conduit includes a copper conduit.

In sum, the cooling system of the present disclosure makes use of phase transition of dielectric liquid to cool heat generating components. Compared to conventional cooling means that solely relies on heat conduction between the heat generating components and the chassis, the cooling system of the present disclosure has the following advantages: (1) simple structure and lower manufacturing cost; (2) the structure of the cooling system does not have to be designed based on the arrangement/configuration of the heat generating component, a single design may be applied to heat generating components with different arrangements/configurations (i.e., higher shareability); (3) dielectric liquid flows due to density difference, and thus components that are blocked and do not contact the housing can also be cooled effectively; (4) can better tolerate local high temperature.

### BRIEF DESCRIPTION OF THE DRAWINGS

To make the objectives, features, advantages, and embodiments of the present disclosure, including those mentioned above and others, more comprehensible, descriptions of the accompanying drawings are provided as follows.

FIG. 1 illustrates a cross-sectional view of a cooling system in accordance with an embodiment of the present disclosure; and

FIG. 2 illustrates a cross-sectional view of a cooling system in accordance with another embodiment of the present disclosure.

### DETAILED DESCRIPTION

For the sake of the completeness of the description of the present disclosure, reference is made to the accompanying drawings and the various embodiments described below. Various features in the drawings are not drawn to scale and are provided for illustration purposes only. To provide full understanding of the present disclosure, various practical details will be explained in the following descriptions. However, a person with an ordinary skill in relevant art should realize that the present disclosure can be implemented without one or more of the practical details. Therefore, the present disclosure is not to be limited by these details.

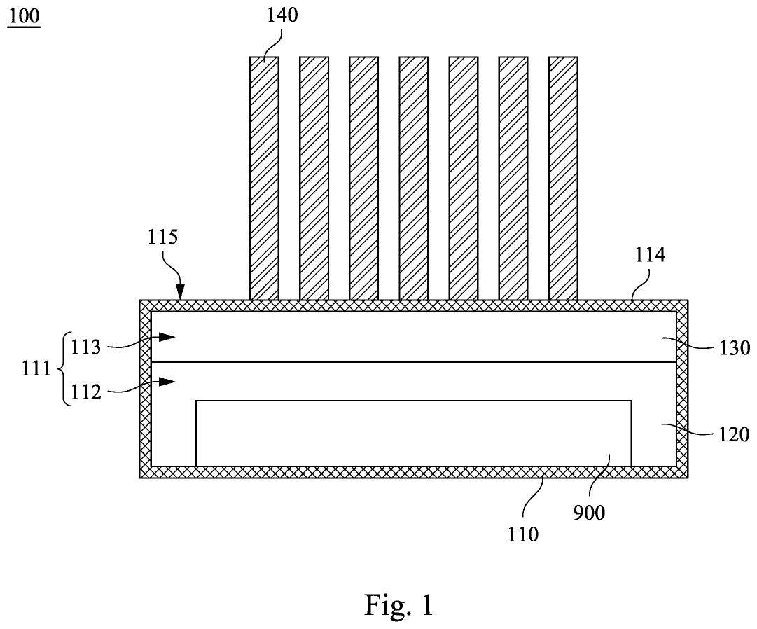

Reference is made to FIG. 1, which illustrates a cross-sectional view of a cooling system 100 in accordance with an embodiment of the present disclosure. The cooling system 100 is configured to cool a heat generating component 900. For example, the heat generating component 900 may be an electronic component such as a chip and an expansion card, or an electronic device including said electronic components. The cooling system 100 includes a housing 110, a dielectric liquid 120 and a dielectric vapor 130. The housing 110 has an airtight accommodating space 111 therein. The accommodating space 111 is configured to accommodate the heat generating component 900. The dielectric liquid 120 partially fills the accommodating space 111 and is configured to contact the heat generating component 900. The dielectric vapor 130 partially fills the accommodating space 111 and is configured to contact the housing 110.

As shown in FIG. 1, specifically, the accommodating space 111 is divided into a liquid region 112 at the bottom and a vapor region 113 outside the liquid region 112. The dielectric liquid 120 is located within the liquid region 112 and the dielectric vapor 130 is located within the vapor region 113. The interface between the liquid region 112 and the vapor region 113 is the liquid surface of the dielectric liquid 120. In some embodiments, the liquid surface of the dielectric liquid 120 is above the heat generating component 900. In other words, the heat generating component 900 is located within the liquid region 112 and is completely immersed in the dielectric liquid 120.

For example, after the dielectric liquid 120 and the heat generating component 900 are placed in the accommodating space 111, the accommodating space 111 has a reserved region (i.e., the vapor region 113) that is not filled by the dielectric liquid 120. Subsequently, the gas in the reserved region is evacuated and the accommodating space 111 is sealed. The dielectric liquid 120 has a lower boiling point under low pressure, and thus can easily be vaporized to form the dielectric vapor 130 to fill the vapor region 113.

The heat generating component 900 generates heat during operation. The dielectric liquid 120, in which the heat generating component 900 is submerged, absorbs the heat generated by the heat generating component 900, and part of the dielectric liquid 120 turns into gaseous dielectric vapor 130 accordingly. The dielectric vapor 130 is driven by pressure difference and flows towards a part of the housing 110 with lower temperature (e.g., a top wall 114 of the housing 110 located away from the heat generating component 900). The dielectric vapor 130 makes contact with the part of the housing 110 with lower temperature and is at least partially condensed into dielectric liquid 120. During the condensation of the dielectric vapor 130, the housing 110 absorbs heat from the dielectric vapor 130, which can be further dissipated to the surrounding environment via natural convection or heat conduction. The dielectric liquid 120 created during condensation returns to the liquid region 112 below and repeats the process discussed above.

As described previously, the cooling system 100 makes use of phase transition of the dielectric liquid 120 to cool the heat generating component 900. Compared to conventional cooling means that solely relies on heat conduction between the heat generating components and the chassis, the cooling system 100 can provide improved cooling efficiency and can better tolerate local high temperature. In addition, temperature variation of the surrounding environment has less impact on the heat generating component 900 immersed in the dielectric liquid 120 since the dielectric liquid 120 has higher specific heat than air. Consequently, the heat generating component 900 is less likely to malfunction.

It is desirable to have the dielectric liquid 120 and the dielectric vapor 130 coexisting in the accommodating space 111 over the operating temperature range of the heat generating component 900, such that the cooling system 100 can make use of phase transition to cool the heat generating component 900. The skilled person may select suitable dielectric liquid 120 based on the operating temperature range of the heat generating component 900, or adjust the pressure (or degree of vacuum) inside the accommodating space 111 to control the boiling point of the dielectric liquid 120. If the boiling point of the dielectric liquid 120 is too high, the heat generated by the heat generating component 900 may not be sufficient to cause the dielectric liquid 120 to boil and vaporize. Conversely, if the boiling point of the dielectric liquid 120 is too low, all of the dielectric liquid 120 may be vaporized into dielectric vapor 130.

In some embodiments, a viscosity of the dielectric liquid 120 is lower than a viscosity of a mineral oil, and/or a surface tension of the dielectric liquid 120 is lower than a surface tension of a mineral oil. Dielectric liquid 120 with said characteristics can easily be removed, facilitating the maintenance of the system. In some embodiments, the dielectric liquid 120 may include refrigerant.

As shown in FIG. 1, in some embodiments, the cooling system 100 further includes a heatsink 140. The heatsink 140 is disposed on an outer surface 115 of the housing 110 and is located on a side of the dielectric vapor 130 away from the dielectric liquid 120. With the heatsink 140, the surface area of the cooling system 100 is enlarged and the heat exchange between the cooling system 100 and the surrounding environment is increased accordingly. In some embodiments, the heatsink 140 includes a plurality of fins installed on the top wall 114 of the housing 110. In some embodiments, cooling fins may also be installed on the outer surface of the sidewalls of the housing 110.

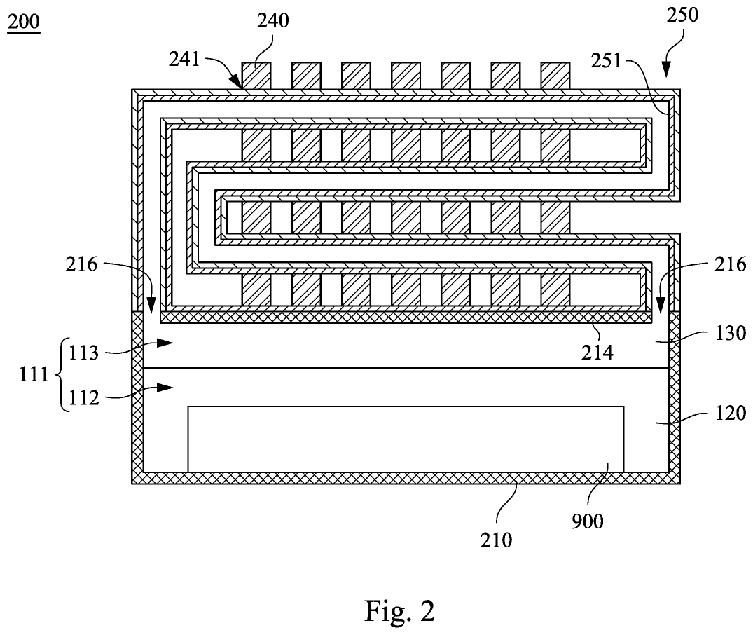

Reference is made to FIG. 2, which illustrates a cross-sectional view of a cooling system 200 in accordance with another embodiment of the present disclosure. The cooling system 200 includes a housing 210, a dielectric liquid 120, a dielectric vapor 130 and a conduit 250. The present embodiment differs from the embodiment shown in FIG. 1 in that the cooling system 200 of the present embodiment further includes the conduit 250 which is in communication with the accommodating space 111 of the housing 210 (specifically, the conduit 250 is in fluid communication with the vapor region 113 of the accommodating space 111) and protrudes out of the housing 210. The internal space of the conduit 250 and the accommodating space 111 collectively form an airtight space.

Following the discussion above, the conduit 250 is configured receive at least part of the dielectric vapor 130. In other words, the dielectric vapor 130 is configured to at least partly flow into the conduit 250 to increase the heat exchange between the dielectric vapor 130 and the surroundings. At least part of the dielectric vapor 130 is condensed into dielectric liquid 120 within the conduit 250. The dielectric liquid 120 created during condensation flows along the conduit 250 to return to the accommodating space 111 of the housing 210. In some embodiments, the housing 210 includes a top wall 214 with two openings 216. The two ends of the conduit 250 are connected to the two openings 216 respectively, and the conduit 250 extends above the housing 210. In some embodiments, the dielectric liquid 120 created during condensation in the conduit 250 returns to the accommodating space 111 of the housing 210 under the guidance of gravity. In some embodiments, the conduit 250 has a wick structure 251 on its inner surface, and the dielectric liquid 120 created during condensation in the conduit 250 returns to the accommodating space 111 of the housing 210 under the guidance of the wick structure 251.

In some embodiments, the conduit 250 may be paired up with a heatsink 240 to further increase cooling efficiency. The heatsink 240 has at least one through hole 241. The conduit 250 passes through the through hole 241 and contacts the heatsink 240. In some embodiments, the heatsink 240 includes a plurality of fins and a plurality of through holes 241 that are formed on the fins and are arranged into a plurality of rows. The conduit 250 extends back and forth to pass through the through holes 241 (and the space between two neighboring fins), so as to increase the contact area between the conduit 250 and the heatsink 240. In some embodiments, some of the through holes 241 are located on the upper ends of the fins (i.e., the end of the fin away from the housing 210). The dielectric vapor 130 is guided through the upper ends of the fins, which has lower temperature, by the conduit 250, thereby increasing cooling efficiency. For example, the conduit 250 may include a copper conduit. Alternatively, the conduit 250 may be made of other materials having high thermal conductivity.

In sum, the cooling system of the present disclosure makes use of phase transition of dielectric liquid to cool heat generating components. Compared to conventional cooling means that solely relies on heat conduction between the heat generating components and the chassis, the cooling system of the present disclosure has the following advantages: (1) simple structure and lower manufacturing cost; (2) the structure of the cooling system does not have to be designed based on the arrangement/configuration of the heat generating component, a single design may be applied to heat generating components with different arrangements/configurations (i.e., higher shareability); (3) dielectric liquid flows due to density difference, and thus components that are blocked and do not contact the housing can also be cooled effectively; (4) can better tolerate local high temperature.

Although the present disclosure has been described by way of the exemplary embodiments above, the present disclosure is not to be limited to those embodiments. Any person skilled in the art can make various changes and modifications without departing from the spirit and the scope of the present disclosure. Therefore, the protective scope of the present disclosure shall be the scope of the claims as attached.

What is claimed is:

1. A cooling system, comprising:
a housing having an accommodating space, the accommodating space being configured to accommodate a heat generating component;
a dielectric liquid partially filling the accommodating space and configured to contact the heat generating component; and
a dielectric vapor partially filling the accommodating space and configured to contact the housing.

2. The cooling system of claim 1, wherein the heat generating component is completely immersed in the dielectric liquid.

3. The cooling system of claim 1, wherein a viscosity of the dielectric liquid is lower than a viscosity of a mineral oil.

4. The cooling system of claim 1, wherein a surface tension of the dielectric liquid is lower than a surface tension of a mineral oil.

5. The cooling system of claim 1, further comprising a heatsink disposed on an outer surface of the housing.

6. The cooling system of claim 5, wherein the heatsink is located on a side of the dielectric vapor away from the dielectric liquid.

7. The cooling system of claim 5, wherein the heatsink comprises a plurality of fins.

8. The cooling system of claim 1, further comprising a conduit in communication with the accommodating space and protruding out of the housing, wherein the dielectric vapor is configured to at least partly flow into the conduit.

9. The cooling system of claim 8, further comprising a heatsink disposed on an outer surface of the housing, the heatsink having at least one through hole, the conduit passing through the through hole and contacting the heatsink.

10. The cooling system of claim 8, wherein the conduit comprises a copper conduit.
